(19) United States
(12) Patent Application Publication
(10) Pub. No.: US 2008/0061744 A1
(43) Pub. Date: Mar. 13, 2008

(54) Portable information recording /reproduction device

(75) Inventors: Toshihiro Morohoshi, Kawasaki-shi (JP); Sumio Sakai, Osato-gun (JP); Toshiaki Matsubayashi, Ichikawa-shi (JP); Satoshi Kazuta, Tachikawa-shi (JP); Masanori Watanuki, Ome-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/898,423

(22) Filed: Sep. 12, 2007

(30) Foreign Application Priority Data
Sep. 13, 2006 (JP) 2006-248481

(51) Int. Cl. G01R 31/36; G06F 1/26; H01M 10/48; H02J 7/00

(52) U.S. Cl. 320/136

(57) ABSTRACT

According to one embodiment, in order to manage the remaining capacity of a secondary battery of an information recording/reproduction device, the remaining capacity of the secondary battery which supplies electric power to the whole device including a storage medium is monitored in accordance with current supply capacity and in accordance with voltage supply capacity. The remaining capacity is displayed on a display in accordance with the current supply capacity. The whole device is stopped when one of the current supply capacity and the voltage is below a system stop level indicating the electric power required on the startup of the storage medium.

### CROSS-REFERENCE TO RELATED APPLICATIONS

This application is based upon and claims the benefit of priority from Japanese Patent Application No. 2006-248481, filed Sep. 13, 2006, the entire contents of which are incorporated herein by reference.

### BACKGROUND

1. Field

One embodiment of the present invention relates to a media player (music/image/video information recording/reproduction device) mainly used in a portable manner, and more particularly, it relates to the management of a voltage during an operation by a built-in secondary battery and to the protection of internal units and data on the occurrence of a sudden voltage drop.

2. Description of the Related Art

Recently, portable information recording/reproduction devices (media players) have been widely used, and these devices are mainly used in a portable manner and are capable of reproducing, as needed (anytime and anywhere), digitized music data or picture data contained in, for example, a solid-state memory such as a memory card or a hard disk.

The music data and picture data can be obtained in various manners, for example, through optical disks conforming to, for example, compact disk (CD) standards or DVD standards, or through public broadcasting provided using space waves (ground waves) or a broadcast satellite, or through downloading by access to a server (distribution site) via, for example, the Internet.

The portable information recording/reproduction device is, for its characteristics, mostly activated by a built-in secondary battery.

On the other hand, when a sudden voltage drop occurs in the secondary battery during access to the hard disk, that is, during the reading of data from the hard disk, data stored in the hard disk is damaged and the next data reproduction might be impossible.

Thus, the remaining amount (remaining capacity) of the battery is constantly monitored, and the device is stopped as required. Moreover, it goes without saying that the remaining amount of the battery varies in accordance with the number of simultaneously operated internal units (devices) and peripheral circuits (elements) counted as applications (data processing programs).

For example, Japanese Patent No. 2928178 has disclosed a portable wireless information terminal device which monitors the switching on/off of the power source of a peripheral circuit and which requests to detect a battery voltage for updating data on the remaining amount of the battery when the peripheral circuit is switched on or off.

According to Japanese Patent No. 2928178, the remaining amount of the battery is detected when the peripheral circuit is switched on or off.

However, if the remaining amount of the battery has decreased in the case where the peripheral circuit is continuously turned on, it is often impossible to allow the sudden voltage drop on the startup of the hard disk. Moreover, it can be easily known by analogy that the device might be stopped in an undesired condition where data can be damaged.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary diagram showing an example of a media player (music/image/video information recording/reproduction device) according to an embodiment of the invention;

FIG. 2 is an exemplary diagram showing an example of the appearance characteristics of the media player shown in FIG. 1, according to an embodiment of the invention;

FIG. 3 is an exemplary diagram showing an example of the number of peripheral circuits/peripheral devices which may be simultaneously operated and changes in discharging characteristics (remaining capacity) of a battery (secondary battery) in the media player shown in FIGS. 1 and 2, according to an embodiment of the invention;

FIG. 4 is an exemplary diagram showing an example of the procedure of stopping the player in accordance with the discharging characteristics (remaining capacity) of the battery (secondary battery) of the media player shown in FIG. 3, according to an embodiment of the invention;

FIG. 5 is an exemplary diagram showing another example of the procedure of stopping the player in accordance with the discharging characteristics (remaining capacity) of the battery (secondary battery) of the media player shown in FIG. 3, according to an embodiment of the invention; and

FIG. 6 is an exemplary diagram showing an example of the relation between the number of peripheral circuits/peripheral devices which may be simultaneously operated and the remaining capacity (termination condition) of the battery (secondary battery) of the media player shown in FIG. 3, according to an embodiment of the invention. According to an aspect of the invention, there is provided an optical pickup comprising:

### DETAILED DESCRIPTION

Various embodiments according to the invention will be described hereinafter with reference to the accompanying drawings. In general, according to one embodiment of the invention, a portable information recording/reproduction device comprising: a storage medium operated by predetermined electric power; a secondary battery which supplies electric power to the whole device including the storage medium; a display which indicates information held in the storage medium and the remaining capacity of the secondary battery; a first internal unit configured to operate simultaneously or in parallel with the storage medium; a second internal unit configured to operate simultaneously or in parallel with the storage medium; a monitor which monitors the voltage supply capacity of the secondary battery; and a controller which monitors the remaining capacity of the secondary battery obtained in accordance with the monitor and which displays an indication on the display to stop the first or second internal unit when the remaining capacity of the secondary battery is below a predetermined level.

According to an embodiment of this invention will hereinafter be described with reference to the drawings.

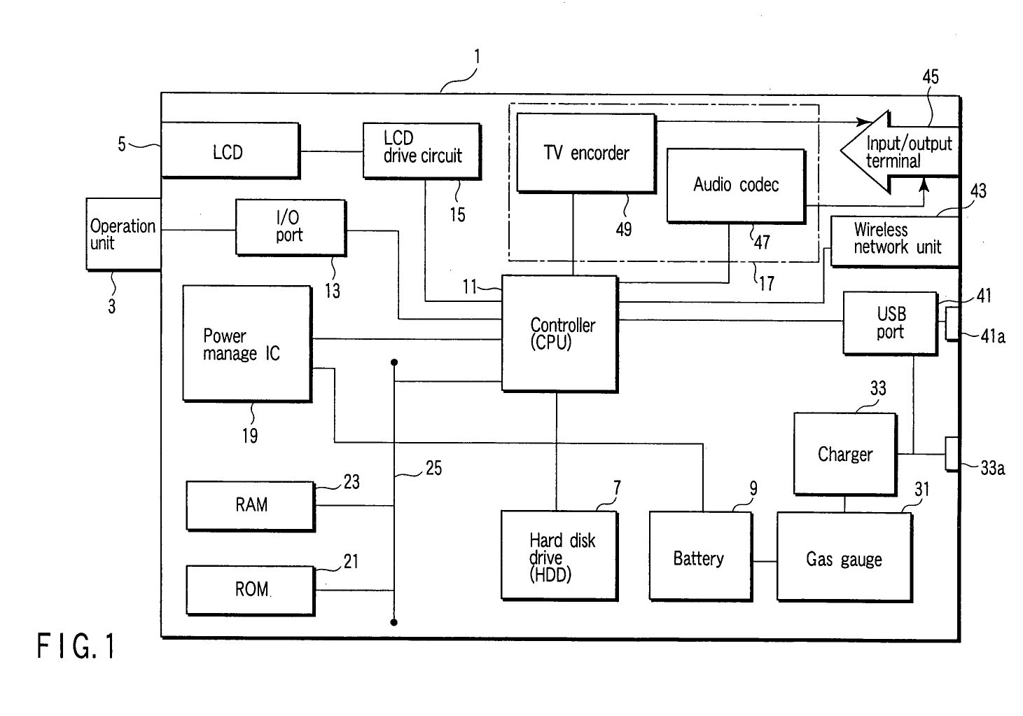

FIG. 1 is a schematic block diagram explaining the main configuration of a media player (music/image/video information recording/reproduction device) mainly used in a portable manner to which one embodiment of this invention is applied.

A media player (music/image/video information recording/reproduction device) 1 shown in FIG. 1 has: an operation unit 3 used to input control signals from a user and to input selection instruction signals; an LCD panel (liquid crystal display) 5 capable of displaying, for example, the file name of a currently played audio/music program, and moving images or still images which are reproductions of character information or picture data contained in an audio program; a hard disk drive (hereinafter represented as HDD) 7 provided with a storage capacity of, for example, several giga (G) bytes to several ten G bytes; a battery (secondary battery) 9 which serves as a power source when the media player is mainly used in a portable manner; a CPU 11 which is a main control unit; etc. In addition, the HDD 7 may be a unitized “mobile disk” detachable from the player 1.

The CPU 11 is connected to an input/output (I/O) port 13 for accepting the control signals input by the user operation on the operation unit 3, a display driver (LCD drive circuit) 15 for displaying images and character strings to be displayed on the LCD panel 5, an output unit 17 for converting picture data or audio/music data held in the HDD 7 into an analog output, a power management integrated circuit (IC) 19 for managing electric power provided by the battery 9, that is, a predetermined voltage and a permitted current, etc.

Furthermore, the CPU 11 is connected to a read only memory (ROM) 21 which is a system memory used to reproduce data stored in the HDD 7 and record data in the HDD 7 and to control, for example, the startup of the HDD 7 or the turning on/off of a main power source not shown, and a work memory, that is, a random access memory (RAM) 23 for temporarily holding, for example, control information or a command corresponding to the (input) control signal and for buffering a certain amount of data read from the HDD 7 via a control bus 25.

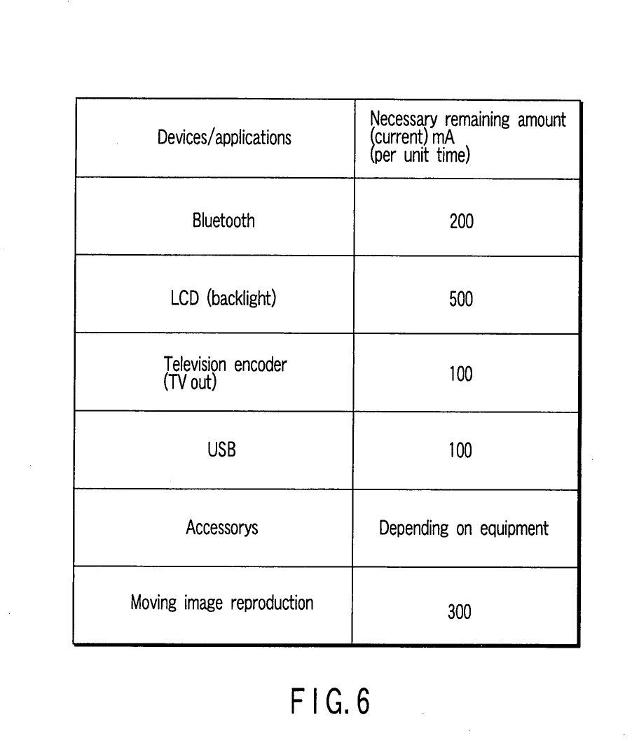

A predetermined DC voltage is supplied to the power management IC 19 to manage the electric power provided by the battery 9, that is, the predetermined voltage and the permitted current. In addition, the value of a current that can be supplied is arbitrarily set within the range of the maximum value of a current that can be supplied by the battery 9 in accordance with the number of internal units operated simultaneously (or in parallel) and the number of operation programs (applications) operated simultaneously (or in parallel) under the control of the CPU 11. Moreover, current values and power consumption necessary to operate peripheral circuits/devices as described later with FIG. 6, that is, internal units (devices) and applications are prestored in, for example, the RAM 23 as firmware of the power management IC 19 or the CPU 11.

A charger 33 is connected to the battery 9 via a gas gauge 31 for monitoring the discharge state, that is, voltage supply capacity and current supply capacity of the battery 9. In addition, the charger 33 can be configured to directly accept a commercial power source (AC 100V), but in this example, a DC voltage decreased/converted to a direct current (DC) of about 5V is generally input from a power supply input unit 33a by an unshown external power supply unit in order to reduce the size of the player 1.

In addition, the CPU 11 is connected to a universal serial bus (USB) port 41 which serves as the supply source of picture data (including character data) and music data (including audio data) and which is used to pass data from/to, for example, a personal computer, a wireless network (wireless local area network) unit (communication unit) 43, an output terminal 45 used for ordinary analog output, etc.

The USB port 41 is used to transfer the music data (audio data) to an external device such as an audio-only player (USB flash memory player) containing a semiconductor memory or a USB speaker from the player 1 via a USB connector 41a and to input music/audio signals from a microphone (external input). In addition, for example, a card slot (multiadapter) can be connected to the USB connector 41a to enable the passage of data from/to a semiconductor memory such as an “SD card”, a “mini-SD card (trademark)”, a “compact flash (trademark)” or a “memory stick (trademark)” which is a storage medium independent from the HDD 7.

It goes without saying that the wireless network unit 43 may be only provided with Bluetooth compliant with the protocol of a (high-speed) communication standard using radio waves at 2.4 GHz and 5.2 GHz bands, may be only provided with a general purpose wireless LAN device compliant with IEEE802.11a/b/g, or may be provided with a combination of the two. In other words, when the wireless LAN device or Bluetooth is incorporated, data can be passed to/from, for example, server computers or personal computers located in households or in a specific range which satisfies predetermined conditions. Therefore, for example, the player 1 can be brought to, for example, a download center running in town to directly download contents (which often have to be paid for).

Music or sound demodulated to an analog signal by an audio codec 47 provided in the output unit 17 is supplied to the output terminal 45 used for the analog output. Thus, for example, headphones or a speaker with an amplification function are attached to the output terminal 45 to play the music or sound. It should be understood that the output from the output terminal 45 can be input to an amplifier (not shown) and a speaker (not shown) can then be connected to the amplifier to obtain a higher sound volume. In addition, an analog signal directly input from an unshown microphone or a line input (external input) terminal can be A/D converted and input as a digital signal to the audio codec 47.

The output terminal 45 is also provided with a television (TV) encoder (video encoder) 49 which is disposed in the output unit 17. Thus, the picture data held in, for example, the HDD 7 can be transferred to and played on an unshown monitor unit or television set.

In the player 1 described above, data such as precompressed music data, image data or video data (contents) are recorded in the HDD 7 in accordance with a predetermined rule. In addition, the following methods are used for the compression of data, such as MP3, WMA, etc., for the compression of the music data, JPG, GIF, BMP, etc., for the compression of the image data, and WMV, MPEG, etc., for the compression of the video data. Although not described in detail, the data stored in the HDD 7 can also be saved in an encrypted format to only permit direct playback using the player 1 and the output to, for example, an external speaker in the form of an analog signal, in order to prevent copying (except for copying for which the number of times is determined) other than copying for “private use” defined by the Copyright Act.

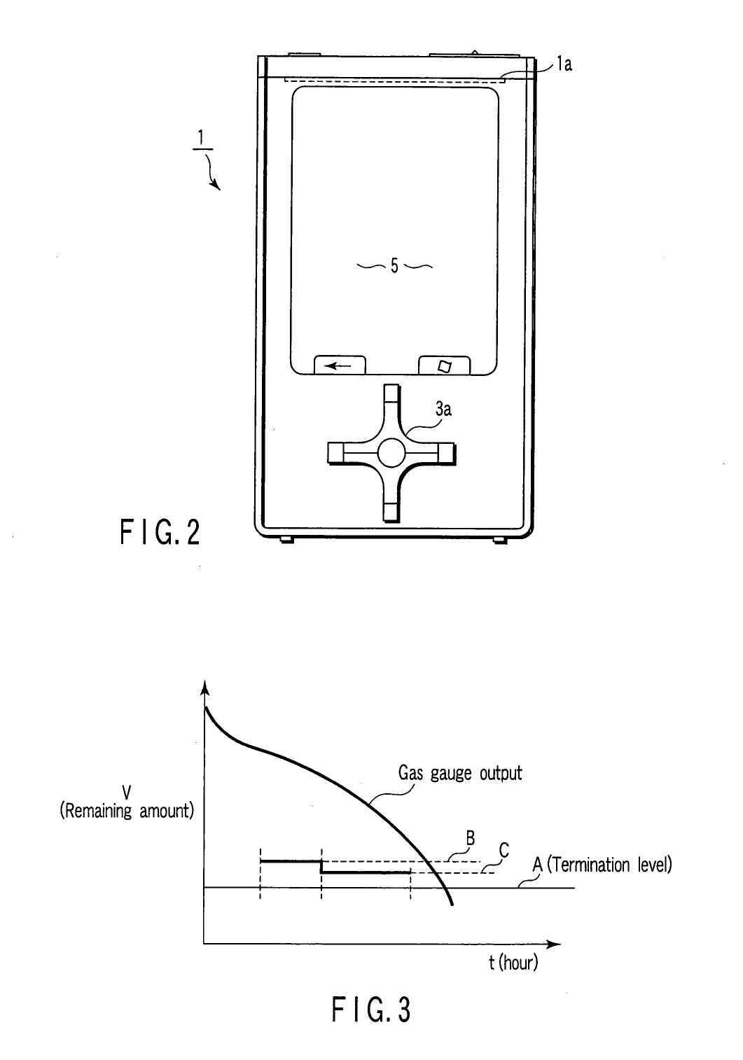

In addition, as the appearance of the player 1 is shown in FIG. 2, the operation unit 3 includes a multifunction button 3a used to input control commands for instructing to start or stop the playback of music/image/video, for switching information displayed on the LCD 5 and for scrolling song lyrics or character information for a program displayed on the LCD 5. For example, when a central button is pushed, the multifunction button 3a can input an on-signal for instructing to start or stop the playback mentioned above. When any one of four-direction (generally called “vertical and horizontal”) buttons is pushed, the multifunction button 3a enables the input of a control command (instruction) to scroll, for example, the image or character strings displayed on the LCD 5 in a direction of the button to which force is applied. Moreover, the wireless network unit 43 and an antenna la for wireless communications with the outside are provided at predetermined positions of the player 1. In addition, the antenna 1a is preferably provided in a part of a member forming the player 1 for which a nonmetal material is used, for example, on the periphery of the LCD 5 or in the vicinity of an unshown power supply switch on the side surface of the player 1.

On the other hand, a relatively high electric power (a high value of a current released from the battery 9) is required on startup because the HDD 7 (hard disk drive) includes a motor. Thus, in a device (portable media player) using the HDD 7, reading and stopping are repeated to decrease power consumption so that a certain amount of data is read from the recording medium (HDD 7) and buffered in the RAM 23 and then the driving of the HDD 7 is stopped.

Therefore, for example, as shown in FIG. 3, the voltage (remaining capacity) of the battery 9 is constantly monitored in the player (system) 1 so that it may not be less than a system termination condition (indicated by “A” in FIG. 3) which enables a safe stop, in order to prevent the player (system) 1 from being suddenly stopped because of the impossibility of the next data reproduction (necessity for a reset operation) due to damage to the data stored in the HDD 7 from a sudden voltage drop in the battery 9 during access to the HDD 7, that is, during the reading of the data from the HDD 7.

Furthermore, it goes without saying that the remaining capacity of the battery 9 is changed as needed in accordance with the on-state (number) of peripheral circuits/peripheral devices which may be simultaneously operated, that is, peripherals which are internal units (devices) or applications (operation programs). In addition, in FIG. 6, the necessary remaining capacity corresponding to an accessory section indicates devices to be connected to, for example, the USB port 41, and shows that power consumption (necessary remaining capacity) varies depending on the device.

In other words, this means that the operation of an arbitrary number of peripherals can be stopped to continuously operate the system (player) 1 when the remaining capacity of the battery 9 has decreased. For example, in FIG. 3, the termination condition is set to a level indicated by “B” or “C” from the system termination condition (“A”) in accordance with the number of simultaneously operated peripherals, such that the system (player) 1 can be safely stopped even if the remaining capacity of the battery 9 has decreased.

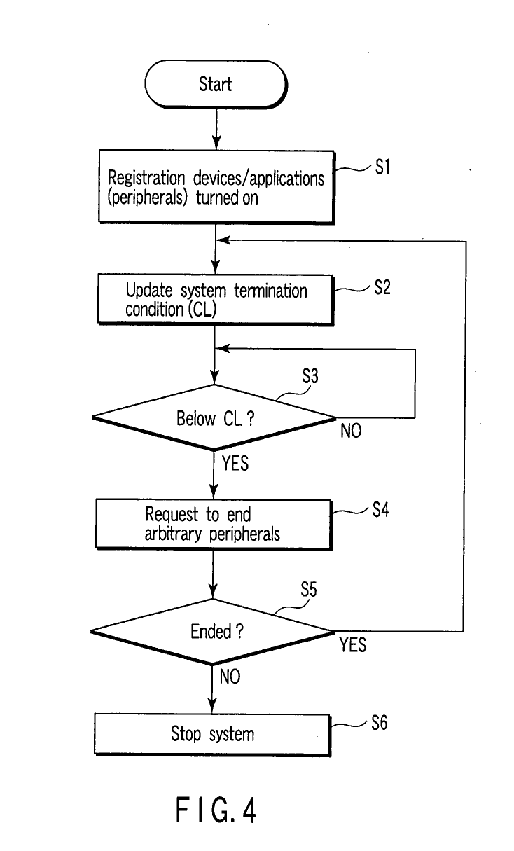

FIG. 4 shows one example (voltage management method) of the operation of the system (player) 1 for setting the termination condition with the arbitrary number shown in FIG. 3. In addition, the remaining capacity of the battery 9 is monitored using the result (“remaining current supply capacity”) of monitoring the output of the gas gauge 31 and the result (“remaining voltage supply capacity”) of monitoring a voltage monitor output ADC of the power management IC 19.

First, the peripherals that can be operated simultaneously or in parallel are registered in the firmware of the power management IC 19 or the CPU 11 or in the RAM 23. That is, the peripherals are stored on, for example, a table as shown in FIG. 6 in the firmware or the RAM 23.

After the peripherals are registered, the system termination condition (CL) is updated. That is, the termination condition already described with FIG. 3 is updated from “A” to “B” (S2).

Subsequently, the remaining capacity of the battery 9 is monitored to check whether it is higher than or less than the termination condition CL (temporary termination condition “B”) (S3).

When it is detected in step S3 that the remaining capacity of the battery 9 is less than the (temporary termination condition “B”) (S3-Y), the LCD 5 indicates a message (alert) telling, for example, “Remaining capacity of battery has decreased. Stop arbitrary programs/internal units (devices).” (S4).

If the arbitrary programs/internal units (devices) are turned off in response to the alert in step S4 (S5-Y), the remaining capacity of the battery, that is, the temporary termination condition “B” is updated in accordance with a change in the number (power consumption) of the stopped arbitrary programs/internal units (devices), and the temporary termination condition is changed to, for example, “C” (S2 to S5 are repeated).

When no programs/internal units (devices) are turned off in spite of the alert in step S4 (S5-N), the operation of the system (player) 1 is stopped in accordance with the remaining capacity of the battery, that is, the temporary termination condition “B”.

Thus, the remaining capacity of the battery is reported to the user and the arbitrary number of programs/internal units are temporarily stopped (ended), such that, while a relatively high voltage required for the rotation of the HDD 7 is left as the termination condition, it is possible to prevent an abnormal end of the system, that is, for example, the impossibility of the next data reproduction due to damage to the data stored in the HDD 7 from a sudden voltage drop in the battery 9 during the reading of the data from the HDD 7. For example, the remaining capacity (time available to playback) of the battery 9 is increased by turning off the backlight of the LCD 5 or by canceling, for example, the output of moving images or character strings to an external monitor/television set by the television encoder 49 of the output unit 17.

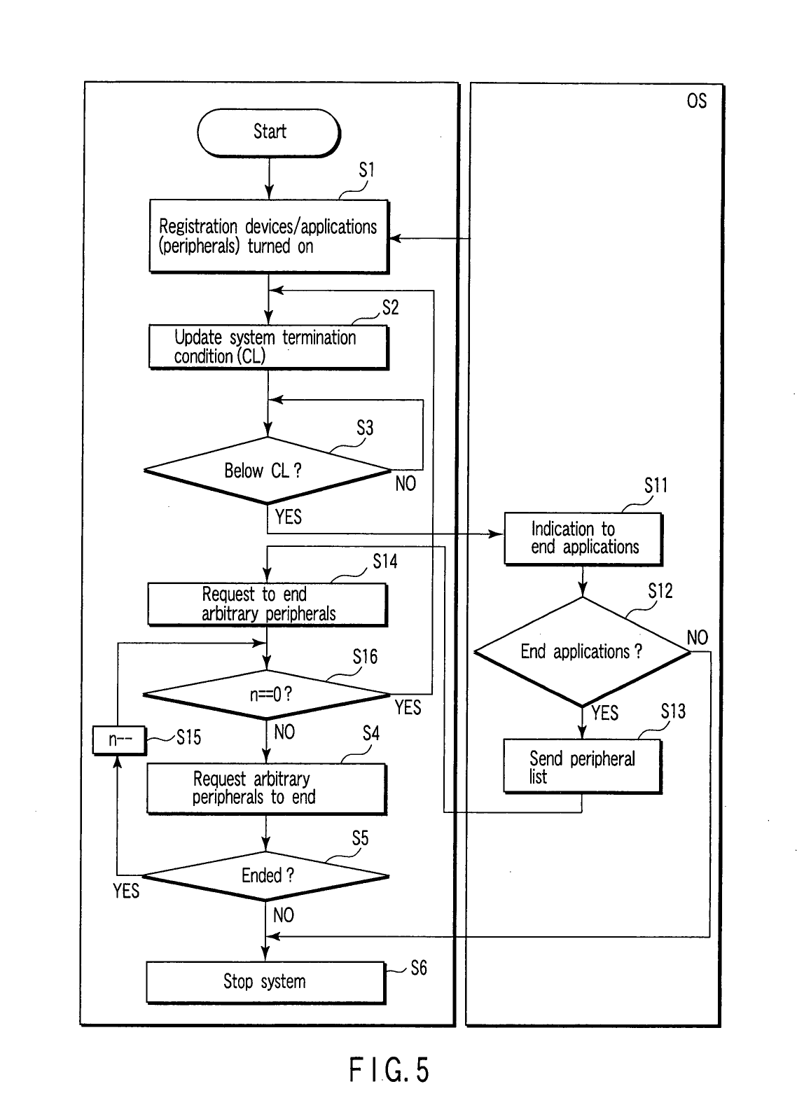

More specifically, as shown in FIG. 5, a power source monitoring unit for monitoring the power source is started on the side of an operation system (OS, stored as firmware in the CPU 11). In addition, the power source monitoring unit is generally provided as driver software.

When the power source monitoring unit has detected that the remaining capacity of the battery 9 is less than the (temporary termination condition “B”) (S3-Y), this is reported to the CPU 11 (from the power source monitoring unit), and a message (alert) is displayed on the LCD 5 under the control of the CPU 11 to urge to stop arbitrary peripherals (applications or devices), for example, “Remaining capacity of battery has decreased. Stop arbitrary programs/internal units (devices).” (S11).

If the user selects here to end the currently executed application (S12-Y), a peripheral list linked to this application is sent to the power source monitoring unit (S13).

Then, the peripheral list is acquired in the power source monitoring unit (S14), and the peripherals are terminated (S4).

When all the peripherals on the peripheral list are ended (S5-Y, S15, S16), the system termination condition (CL) is updated (S2).

When no peripherals are stopped in step S12 (S12-N), the system (player) 1 is stopped (S6) in accordance with the system termination condition (CL).

In addition, it goes without saying that, in step S2, whether there are any peripherals to be stopped together is checked when the arbitrary number of or several peripherals are stopped in step S4, and when there are peripherals to be stopped together, the electric power consumed by these peripherals is also reflected to the updating of the termination condition associated with the remaining capacity of the battery 9.

Thus, when the remaining capacity of the battery 9 has decreased, the operations of an arbitrary number of peripherals can be selectively stopped by the user to continuously operate the system (player) 1. Therefore, the termination condition is changed as needed in accordance with the number of simultaneously operated peripherals, such that the system (player) 1 can be safely stopped even if the remaining capacity of the battery 9 has decreased. That is, when the remaining capacity of the battery 9 has decreased, a selection screen to select the end of an application or the end of the entire system is displayed on the LCD 5 using a graphical user interface (GUI) to urge the user to make a selection, thereby enabling the user to select the stoppage of the system or the cancellation of some applications. In addition, it goes without saying that the system may be automatically stopped in accordance with a setting arranged in advance on the side of the CPU 11 (OS).

As described above, according to the arbitrary embodiment of this invention, the system is safely stopped when the remaining capacity of the battery is below a predetermined level in the portable media player.

Thus, the system is prevented from improper stoppage, for example, the impossibility of the next data reproduction (necessity for a reset operation) due to damage to the data stored in the storage medium from a sudden voltage drop in the battery. This enhances the convenience for the user.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the storage medium is not limited to the hard disk drive, and it goes without saying that a storage system which uses a motor to rotate a recording medium disk may be incorporated, such as an optical disk drive which uses an optical disk.

What is claimed is:

1. A portable information recording/reproduction device comprising:
a storage medium operated by predetermined electric power;
a secondary battery which supplies electric power to the whole device including the storage medium;
a display which indicates information held in the storage medium and the remaining capacity of the secondary battery;
a first internal unit configured to operate simultaneously or in parallel with the storage medium;
a second internal unit configured to operate simultaneously or in parallel with the storage medium;
a monitor which monitors the voltage supply capacity of the secondary battery; and
a controller which monitors the remaining capacity of the secondary battery obtained in accordance with the monitor and which displays an indication on the display to stop the first or second internal unit when the remaining capacity of the secondary battery is below a predetermined level.

2. The portable information recording/reproduction device according to claim 1, wherein
the controller detects that neither the first nor second internal unit is stopped, and then stops the whole device including the storage medium.

3. The portable information recording/reproduction device according to claim 1, wherein
the controller updates a system termination condition to stop the whole device including the storage medium when at least one of the first and second internal units is stopped.

4. The portable information recording/reproduction device according to claim 1, wherein
when at least one of the first and second internal units is stopped, the controller judges whether there are any other internal units to be stopped together and updates a system termination condition to stop the whole device including the storage medium.

5. A method of managing the remaining capacity of a secondary battery of a portable information recording/reproduction device, the method comprising:
monitoring the remaining capacity of the secondary battery which supplies electric power to the whole device including a storage medium, the number of internal units or operation programs operated simultaneously or in parallel, and the value of a current necessary for the operations of the internal units or operation programs;
detecting that the remaining capacity of the secondary battery which supplies electric power to the whole device including the storage medium has decreased to a level which requires to stop arbitrary internal units or operation programs;
requesting to stop the arbitrary internal units or operation programs in accordance with the result of the detection; and
updating the level of a system stop voltage to stop the whole device when the arbitrary internal units or operation programs are stopped.

6. The method according to claim 5, wherein
the arbitrary internal units or operation programs are requested to stop in accordance with the result of the detection; and
the whole device is stopped when neither the internal units nor operation programs are stopped.

7. The method according to claim 5, wherein
the arbitrary internal units or operation programs are requested to stop in accordance with the result of the detection; and
when the arbitrary internal units or operation programs are stopped, whether there are any other internal units to be stopped together is judged, and the level of a system stop voltage to stop the whole device is updated.
